(19) United States
(12) Patent Application Publication
(10) Pub. No.: US 2018/0175888 A1
(43) Pub. Date: Jun. 21, 2018

(54) EFFICIENT ENCODING/DECODING FOR MULTIPLE-INPUT MULTIPLE-OUTPUT OPERATING WITH TWO CODEWORDS

(71) Applicant: Nokia Technologies Oy, Espoo (FI)

(72) Inventors: Keeth Saliya JAYASINGHE, Piliyandala (LK); Karri Markus RANTA-AHO, Espoo (FI); Mihai ENESCU, Espoo (FI)

(21) Appl. No.: 15/837,112

(22) Filed: Dec. 11, 2017

Related U.S. Application Data
(60) Provisional application No. 62/435,465, filed on Dec. 16, 2016.

(51) Int. Cl. H03M 13/29; H04L 1/00; H03M 13/00

(52) U.S. Cl. CPC H03M 13/2906; H04L 1/0009; H04B 7/0413; H03M 13/616; H04L 1/0061

(57) ABSTRACT

Various communication systems may benefit from efficient encoding and decoding. For example, certain multiple-input multiple-output devices may benefit from efficient encoding and decoding while operating with two codewords. A method can include receiving a first codeword and a second codeword. The method can also include segmenting the first codeword and the second codeword to provide similar sub-matrix dimensions. The method can further include outputting similarly sub-matrix dimensioned code blocks of the first codeword and the second codeword as a first code blocks and second code blocks.

### BACKGROUND

### Field

Various communication systems may benefit from efficient encoding and decoding. For example, certain multiple-input multiple-output devices may benefit from efficient encoding and decoding while operating with two codewords.

### Description of the Related Art

The number of codeword(s) to support with multiple-input multiple-output (MIMO) might have the following characteristics. The number of codeword(s) per one scheduled physical data channel in new radio (NR) both for downlink (DL) and uplink (UL) can be 1 or 2 codewords for 1-2 MIMO layers. For 3-8 MIMO layers there may be 1, 2, or 3 or even more codewords.

The selection from among these alternatives might take into account performance of non-coherent joint transmission (NC-JT) from two or more beams/transmission reception points (TRPs), overhead in downlink control information (DCI)/uplink control information (UCI), such as acknowledgment (ACK)/negative acknowledgment (NACK) or channel quality indicator (CQI).

Overhead reduction schemes might be applied, such as indication for the maximum number of MIMO layers from TRP, ACK/NACK spatial bundling, and so on. Different modulations might be used in a single codeword. Furthermore, there might be the possibility of a configurable number of codewords per user equipment (UE) by the network (NW).

In long term evolution (LTE), turbo codes always operate with rate 1/3 where encoding and decoding can be performed without changing any particular configurations of the encoder and decoder. When codeword or transport block (TB) is larger, TB can be segmented into several code blocks (CB), and the encoder or decoder can process them together without changing encoder or decoder configuration. With low-density parity-check (LDPC) codes, encoder and decoder use parity check matrices that are always dependent on the code block size and code rates for which support is needed. There can be delays due to the sequential nature of processing, when there are not two parallel encoders/decoders. For example, CBs of the first codeword can be processed prior to the CBs of the second codeword.

Various documents describe LDPC decoder architectures, MIMO codewords and segmentation principles, of which the following are three examples: C. Roth, VLSI Design, Optimization, and Implementation of Channel Decoding in Wireless Systems. Diss. Diss., Eidgenossische Technische Hochschule ETH Zurich, Nr. 22672, 2015; 3GPP TS 36.212; and 5G.212 (KT 5th Generation Radio Access; Multiplexing and channel coding).

FIG. 1 illustrates LDPC decoder design space in three high-level architectures. For more discussion of FIG. 1, see the Ross document mentioned above. Several examples for decoder architectures used for LDPC are shown in FIG. 1, where almost all computation units and routing network depend on the size of the sub-matrix used in the parity check matrix. More specifically, extended base graph (or parity check matrix), i.e., code rate 8/9 to lower rates with the same matrix may be a design guideline. Therefore, code rate does not create encoding or decoding concerns as it uses same base graph. Moreover, different block sizes can be supported by shifting dimension of sub-matrix, which will change the configurations for any decoder architecture shown in FIG. 1. If it is necessary to process two CBs that are having different sub-matrix dimensions, encoder or decoder hardware units may need to adjust accordingly. This may cause encoding and decoding latencies.

Code segmentation in LTE Turbo codes as described in 3GPP TS 36.212, does not depend on the number of codewords. LTE perform segmentation per codeword and it is possible to have two different code block sizes (CBS) for two codewords. Rate matching is often considered with a circular buffer, and has nothing to do with the encoding and decoding steps.

LDPC codes are used in the latest 5G approaches, as described in 5G.212, where supported codewords in MIMO mode are always limited to one codeword. When two codewords are supported, the techniques are not directly applicable to provide efficient encoding/decoding process.

### SUMMARY

In a first aspect thereof the exemplary embodiments of this invention provide a method that comprises receiving a first codeword and a second codeword; segmenting the first codeword and the second codeword based on transport block size and code rate to provide a sub-matrix dimension; and outputting the sub-matrix dimensioned code blocks of the first codeword and the second codeword as a first code blocks and second code blocks.

In a further aspect thereof the exemplary embodiments of this invention provide an apparatus that comprises at least one data processor and at least one memory that includes computer program code. The at least one memory and computer program code are configured, with the at least one data processor, to cause the apparatus, at least to receive a first codeword and a second codeword; segment the first codeword and the second codeword based on transport block size and code rate to provide a sub-matrix dimension; and output the sub-matrix dimensioned code blocks of the first codeword and the second codeword as a first code blocks and second code blocks.

In another aspect thereof the exemplary embodiments of this invention provide an apparatus that comprises at least one data processor and at least one memory that includes computer program code. The at least one memory and computer program code are configured, with the at least one data processor, to cause the apparatus, at least to receive first rate-matched code blocks and second rate-matched code blocks corresponding to a first codeword and a second codeword respectively; rate de-match the first rate-matched code blocks and the second rate-matched code blocks; and output first rate de-matched code blocks and second rate de-matched code blocks corresponding to the first codeword and the second codeword respectively.

### BRIEF DESCRIPTION OF THE DRAWINGS

For proper understanding of the invention, reference should be made to the accompanying drawings, wherein:

FIG. 1 illustrates LDPC decoder design space in three high-level architectures.

FIG. 2 illustrates an encoding and decoding procedure without a coordinated segmentation principle, according to certain embodiments.

FIG. 3 illustrates encoding and decoding procedure with coordinated segmentation, according to certain embodiments.

FIG. 4 illustrates an algorithm to determine the sub-matrix dimension, according to certain embodiments.

FIG. 5 illustrates a method according to certain embodiments.

FIG. 6 illustrates a system according to certain embodiments.

### DETAILED DESCRIPTION

Certain embodiments relate to how to support channel encoding and decoding when the number of codewords is equal to two. LDPC codes can be used as the NR eMBB data coding scheme. LDPC has different encoding/decoding operation than LTE turbo codes, which are not directly applicable to support efficient two-codeword operation, as mentioned above. Certain embodiments provide possible technique(s) to support two-codeword operation with LDPC codes.

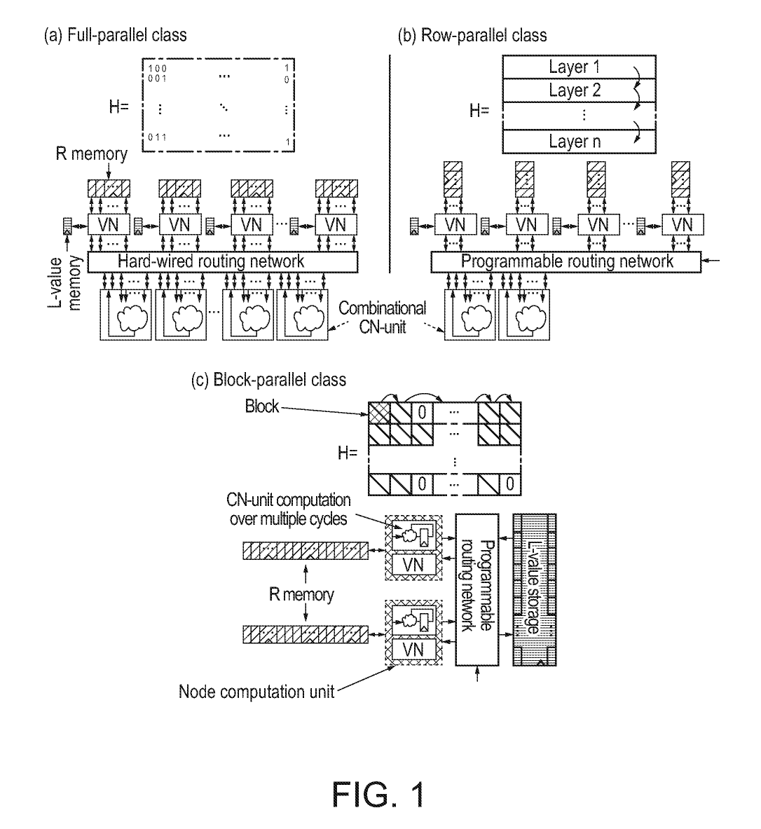

Two-codeword operation with traditional LDPC encoding and decoding is shown in FIG. 1. Codeword 1 and 2 can be segmented without any coordination and separately select the sub-matrix dimension to maximize the operating code block size and to minimize padding requirements. However, the encoder and decoder always operate with fixed sub-matrix size and sequential operation is required for two codewords when code blocks (CBs) have different sub-matrix dimensions. Additional delays, memory requirements, and other hybrid automatic repeat request (HARQ) related issues may limit gains that can be obtained from max block sizes and reducing padding.

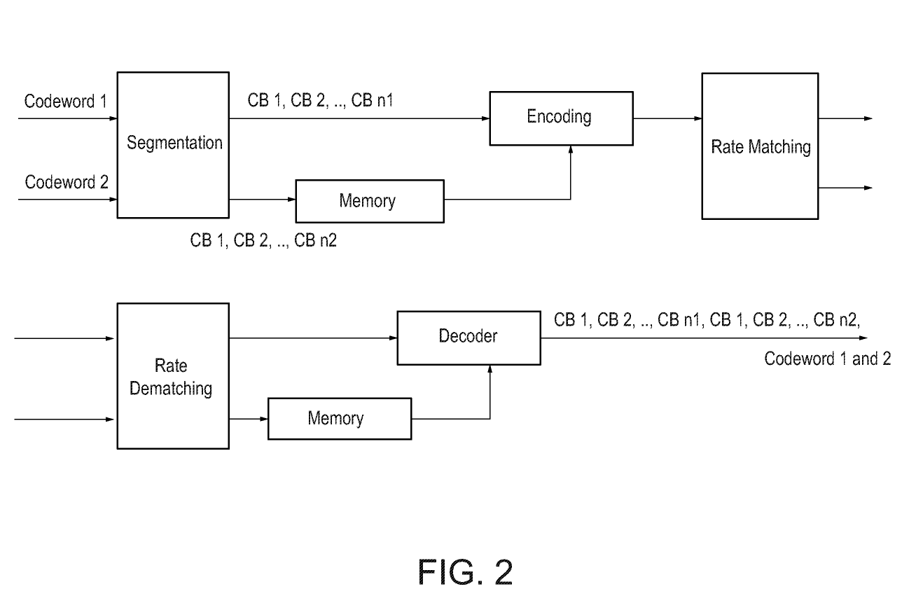

FIG. 2 illustrates an encoding and decoding procedure without a coordinated segmentation principle, according to certain embodiments. FIG. 2 illustrates a sequential encoding/decoding process.

As shown in FIG. 2, the two codewords can be received at a segmentation module, which can segment each of the two codewords into two streams of code blocks, respectively labelled n1 and n2. The second stream can be stored in a memory. Both streams can be provided to encoding. The encoded streams can be provided to rate matching.

A similar process can happen in reverse at receiving. The rate matched streams can be received a rate dematching module. The rate dematching module can provide one of the streams to a memory, and both streams can be provided to the decoder. The decoder can output codewords 1 and 2.

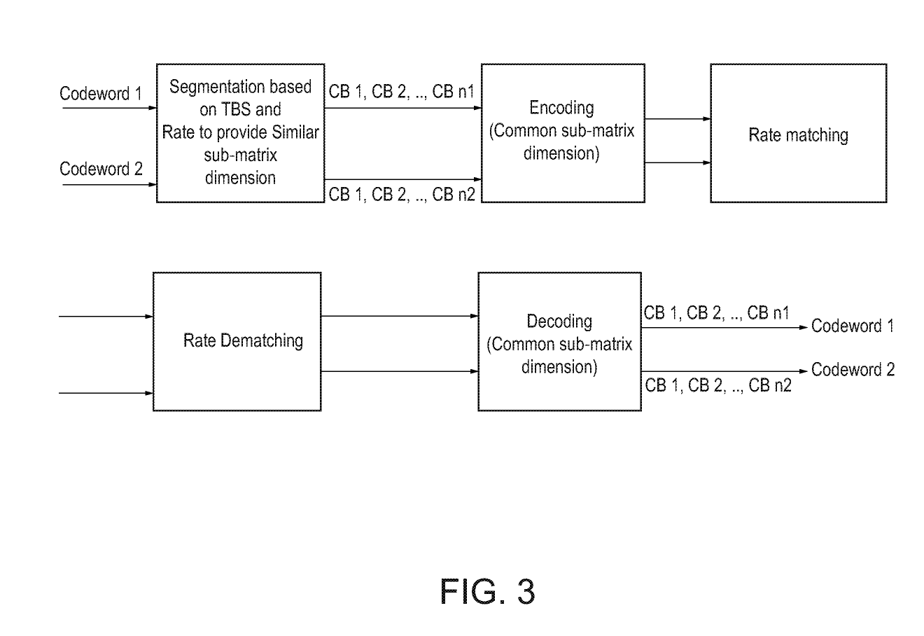

FIG. 3 illustrates encoding and decoding procedure with coordinated segmentation, according to certain embodiments. As shown, combined processing is possible. FIG. 3 shows a method that could be followed to improve the encoding and decoding efficiency by allowing more flexibility to encode and decode different CBs of codewords.

As shown in FIG. 3, a first module can provide segmentation of codewords 1 and 2 based on transport block size (TBS) and rate to provide similar sub-matrix dimensions between the code words. The encoding can then perform encoding with a common sub-matrix dimension. Then rate matching can be performed. At the receiving side, rate dematching can be performed and then decoding can occur with a common sub-matrix dimension, yielding codewords 1 and 2.

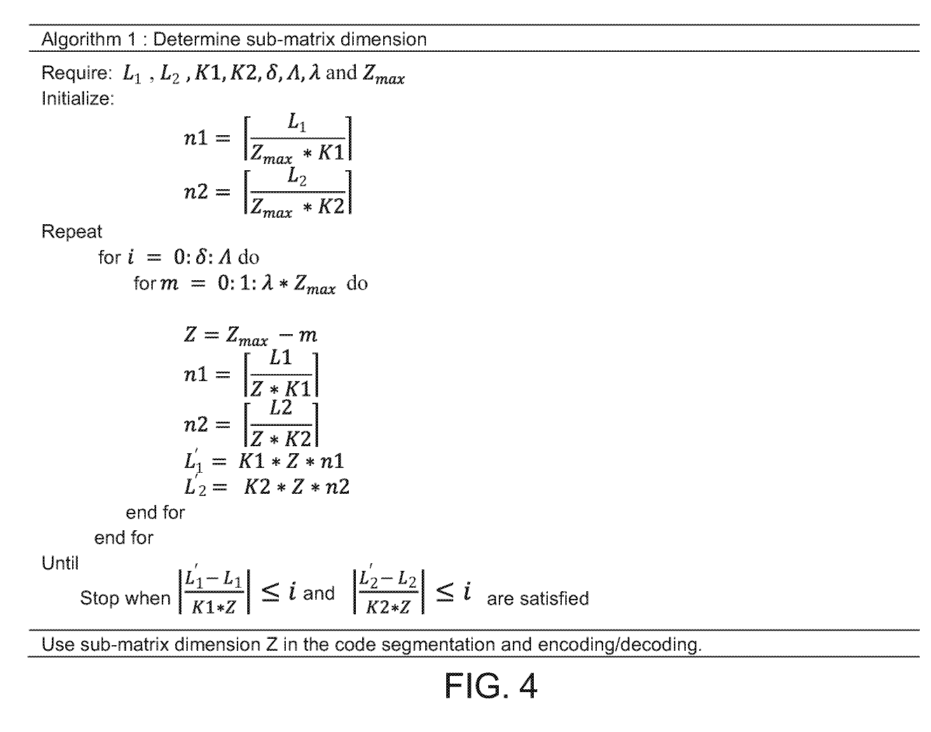

FIG. 4 illustrates an algorithm to determine the sub-matrix dimension, according to certain embodiments. Thus, Algorithm 1 illustrates a method of providing segmentation with common sub-matrix dimension. This method is based on code rate and TBS of two codewords, including cyclic redundancy check (CRC) overhead.

In FIG. 4, L₁ and L₂ denote the TB sizes (TBS) of first and second codeword, n1 and n2 are the enumerated CBs, K1 and K2 are the number of columns associated with the information part of parity check matrices, Λ is the maximum padding constraint and δ is the step size, λ is the allowable fraction (<1) in reducing sub-matrix dimension from the maximum size, and [x] denotes the Ceiling function.

In addition, Λ and λ may provide a trade-off between allowed padding and reducing operating block size. In practice, these details can be fixed and sub-matrix dimensions close to the maximum can be obtained when the transport block sizes are large.

When there is single codeword operation, codeword segmentation can use a different segmentation principle. When the base station and user equipment have multiple encoders or decoders that can be used in parallel, the method of single codeword segmentation can be applied for both codewords.

Radio resource control (RRC) signaling can be used to determine the capabilities of encoding and decoding, then to select the best possible segmentation mechanism.

When both codewords support incremental redundancy (IR) HARQ, the proposed method may be efficient for encoding, as determining the coded block size may not consume much processing as the system may always encode with the lowest code rate. Rate matching can take care of selecting the coded block size matching to the intended code rate.

The segmentation method according to certain embodiments may not require complicated processing as the described approaches to finding the operating sub-matrix dimension has a low number of operations. When the sub-matrix dimension is fixed for two codewords, it may be possible to encode or decode in whatever arrangement is chosen at the encoder and decoder.

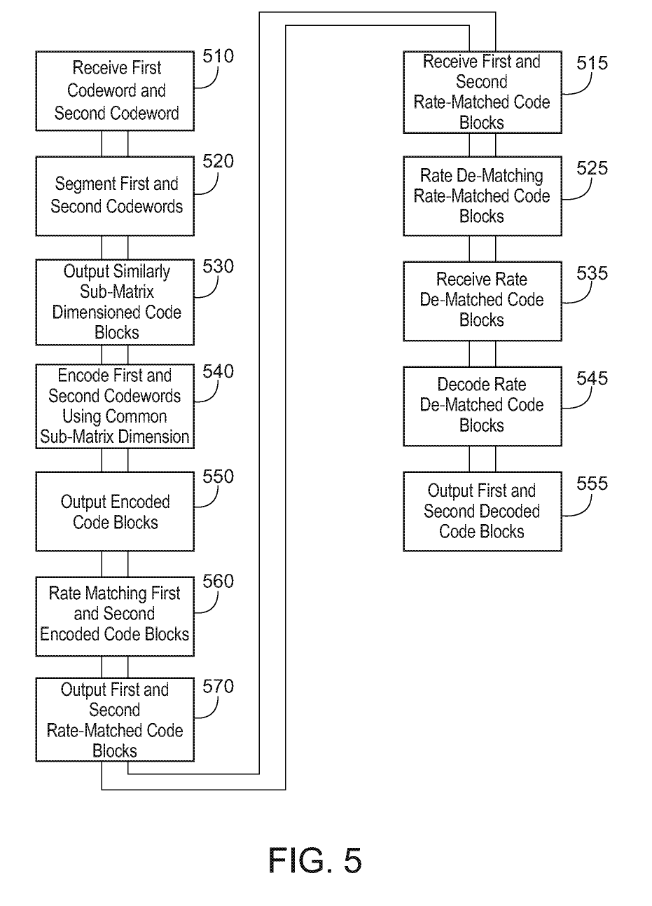

FIG. 5 illustrates a method according to certain embodiments. As shown in FIG. 5, a method can include receiving, at 510, a first codeword and a second codeword. The method can also include, at 520, segmenting the first codeword and the second codeword to provide similar sub-matrix dimensions. The method can further include, at 530, outputting similarly sub-matrix dimensioned code blocks of the first codeword and the second codeword as a first code blocks and second code blocks.

In a variant, the method can further include, at 540, encoding the first code blocks and the second code blocks using a common sub-matrix dimension. The method can additionally include, at 550, outputting first encoded code blocks and second encoded code blocks corresponding to the first codeword and the second codeword respectively.

In a variant, the method can include, at 560, rate matching the first encoded code blocks and second encoded code blocks. The method can further including, at 570, outputting first rate-matched code blocks and second rate-matched code blocks, corresponding to the first codeword and the second codeword respectively.

The above-mentioned features or steps can be performed at a transmitting side. The method can include receiving side features. For example, the method can further include, at 515, receiving first rate-matched code blocks and second rate-matched code blocks. The method can also include, at 525, rate de-matching the first rate-matched code blocks and second rate-matched code blocks to provide first rate de-matched code blocks and second rate de-matched code blocks, corresponding to the first codeword and the second codeword respectively.

The method can also include, at 535, receiving the first rate de-matched code blocks and the second rate de-matched code blocks. The method can further include, at 545, decoding the first rate de-matched code blocks and the second rate de-matched code blocks using a common sub-matrix dimension. The method can additionally include, at 555, outputting first decoded code blocks and second decoded code blocks corresponding to the first codeword and the second codeword respectively.

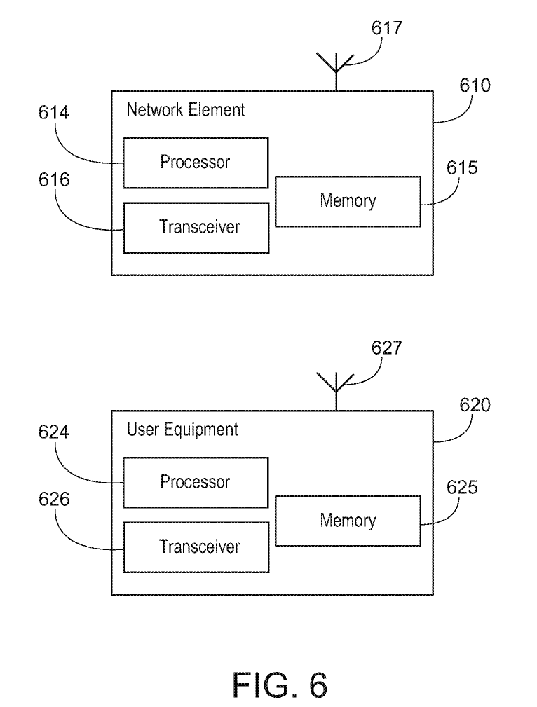

FIG. 6 illustrates a system according to certain embodiments of the invention. It should be understood that each block of the flowchart of FIG. 5 may be implemented by various means or their combinations, such as hardware, software, firmware, one or more processors and/or circuitry. In one embodiment, a system may include several devices, such as, for example, network element 610 and user equipment (UE) or user device 620. The system may include more than one UE 620 and more than one network element 610, although only one of each is shown for the purposes of illustration. A network element can be an access point, a base station, an eNode B (eNB), or any other network element.

Each of these devices may include at least one processor or control unit or module, respectively indicated as 614 and 624. At least one memory may be provided in each device, and indicated as 615 and 625, respectively. The memory may include computer program instructions or computer code contained therein, for example for carrying out the embodiments described above. One or more transceiver 616 and 626 may be provided, and each device may also include an antenna, respectively illustrated as 617 and 627. Although only one antenna each is shown, many antennas and multiple antenna elements may be provided to each of the devices. Other configurations of these devices, for example, may be provided. For example, network element 610 and UE 620 may be additionally configured for wired communication, in addition to wireless communication, and in such a case antennas 617 and 627 may illustrate any form of communication hardware, without being limited to merely an antenna.

Transceivers 616 and 626 may each, independently, be a transmitter, a receiver, or both a transmitter and a receiver, or a unit or device that may be configured both for transmission and reception. The transmitter and/or receiver (as far as radio parts are concerned) may also be implemented as a remote radio head which is not located in the device itself, but in a mast, for example. It should also be appreciated that according to the “liquid” or flexible radio concept, the operations and functionalities may be performed in different entities, such as nodes, hosts or servers, in a flexible manner. In other words, division of labor may vary case by case. One possible use is to make a network element to deliver local content. One or more functionalities may also be implemented as a virtual application that is provided as software that can run on a server.

A user device or user equipment 620 may be a mobile station (MS) such as a mobile phone or smart phone or multimedia device, a computer, such as a tablet, provided with wireless communication capabilities, personal data or digital assistant (PDA) provided with wireless communication capabilities, vehicle, portable media player, digital camera, pocket video camera, navigation unit provided with wireless communication capabilities or any combinations thereof. The user device or user equipment 620 may be a sensor or smart meter, or other device that may usually be configured for a single location.

In an exemplifying embodiment, an apparatus, such as a node or user device, may include means for carrying out embodiments described above in relation to FIG. 5.

Processors 614 and 624 may be embodied by any computational or data processing device, such as a central processing unit (CPU), digital signal processor (DSP), application specific integrated circuit (ASIC), programmable logic devices (PLDs), field programmable gate arrays (FPGAs), digitally enhanced circuits, or comparable device or a combination thereof. The processors may be implemented as a single controller, or a plurality of controllers or processors. Additionally, the processors may be implemented as a pool of processors in a local configuration, in a cloud configuration, or in a combination thereof. The term circuitry may refer to one or more electric or electronic circuits. The term processor may refer to circuitry, such as logic circuitry, that responds to and processes instructions that drive a computer.

For firmware or software, the implementation may include modules or units of at least one chip set (e.g., procedures, functions, and so on). Memories 615 and 625 may independently be any suitable storage device, such as a non-transitory computer-readable medium. A hard disk drive (HDD), random access memory (RAM), flash memory, or other suitable memory may be used. The memories may be combined on a single integrated circuit as the processor, or may be separate therefrom. Furthermore, the computer program instructions may be stored in the memory and which may be processed by the processors can be any suitable form of computer program code, for example, a compiled or interpreted computer program written in any suitable programming language. The memory or data storage entity is typically internal but may also be external or a combination thereof, such as in the case when additional memory capacity is obtained from a service provider. The memory may be fixed or removable.

The memory and the computer program instructions may be configured, with the processor for the particular device, to cause a hardware apparatus such as network element 610 and/or UE 620, to perform any of the processes described above (see, for example, FIG. 5). Therefore, in certain embodiments, a non-transitory computer-readable medium may be encoded with computer instructions or one or more computer program (such as added or updated software routine, applet or macro) that, when executed in hardware, may perform a process such as one of the processes described herein. Computer programs may be coded by a programming language, which may be a high-level programming language, such as objective-C, C, C++, C#, Java, etc., or a low-level programming language, such as a machine language, or assembler. Alternatively, certain embodiments of the invention may be performed entirely in hardware.

Furthermore, although FIG. 6 illustrates a system including a network element 610 and a UE 620, embodiments of the invention may be applicable to other configurations, and configurations involving additional elements, as illustrated and discussed herein. For example, multiple user equipment devices and multiple network elements may be present, or other nodes providing similar functionality, such as nodes that combine the functionality of a user equipment and an access point, such as a relay node.

Certain embodiments may have various benefits and/or advantages. For example, two-codeword operation with LDPC can operate with the same efficiency as with LTE turbo codes. Also, early HARQ feedback for both codewords is possible in certain embodiments when first code blocks are found with errors. Otherwise, the second codeword can wait until the last code block of the TB 1. Furthermore, certain embodiments can reduce additional memory requirements. Moreover, in certain embodiments encoder and decoder operation is efficient, as it does not change shift network and other configurations depending on the code block.

One having ordinary skill in the art will readily understand that the invention as discussed above may be practiced with steps in a different order, and/or with hardware elements in configurations which are different than those which are disclosed. Therefore, although the invention has been described based upon these preferred embodiments, it would be apparent to those of skill in the art that certain modifications, variations, and alternative constructions would be apparent, while remaining within the spirit and scope of the invention.

### List of Abbreviations

TB Transport block

TBS TB size

CB Code block

According to a first embodiment, a method can include receiving a first codeword and a second codeword. The method can also include segmenting the first codeword and the second codeword to provide similar sub-matrix dimensions. The method can further include outputting similarly sub-matrix dimensioned code blocks of the first codeword and the second codeword as a first code blocks and second code blocks.

In a variant, the method can further include encoding the first code blocks and the second code blocks using a common sub-matrix dimension. The method can additionally include outputting first encoded code blocks and second encoded code blocks corresponding to the first codeword and the second codeword respectively.

In a variant, the method can include rate matching the first encoded code blocks and second encoded code blocks. The method can further including outputting first rate-matched code blocks and second rate-matched code blocks, corresponding to the first codeword and the second codeword respectively.

According to a second embodiment, a method can include receiving first rate de-matched code blocks and second rate de-matched code blocks corresponding to a first codeword and a second codeword respectively. The method can also include decoding the first rate de-matched code blocks and the second rate de-matched code blocks using a common sub-matrix dimension. The method can further include outputting first decoded code blocks and second decoded code blocks corresponding to the first codeword and the second codeword respectively.

In a variant, the method can further include receiving first rate-matched code blocks and second rate-matched code blocks. The method can also include rate de-matching the first rate-matched code blocks and second rate-matched code blocks to provide the first rate de-matched code blocks and the second rate de-matched code blocks.

According to third and fourth embodiments, an apparatus can include means for performing the method according to the first and second embodiments respectively, in any of their variants.

According to fifth and sixth embodiments, an apparatus can include at least one processor and at least one memory including computer program code. The at least one memory and the computer program code can be configured to, with the at least one processor, cause the apparatus at least to perform the method according to the first and second embodiments respectively, in any of their variants.

According to seventh and eighth embodiments, a computer program product may encode instructions for performing a process including the method according to the first and second embodiments respectively, in any of their variants.

According to ninth and tenth embodiments, a non-transitory computer readable medium may encode instructions that, when executed in hardware, perform a process including the method according to the first and second embodiments respectively, in any of their variants.

According to eleventh and twelfth embodiments, a system may include at least one apparatus according to the third or fifth embodiments in communication with at least one apparatus according to the fourth or sixth embodiments, respectively in any of their variants.

What is claimed is:

1. A method comprising:
receiving a first codeword and a second codeword;
segmenting the first codeword and the second codeword based on transport block size and code rate to provide a sub-matrix dimension; and
outputting the sub-matrix dimensioned code blocks of the first codeword and the second codeword as a first code blocks and second code blocks.

2. The method as in claim 1, wherein the transport block size includes cyclic redundancy check overhead.

3. The method as in claim 1, wherein the first codeword and the second codeword is segmented with a single codeword segmentation.

4. The method as in claim 1, wherein the segmenting mechanism is selected based on encoding and decoding capabilities determined using radio resource control signaling.

5. The method as in claim 1, wherein the sub-matrix dimension is determined based on at least one of the transport block sizes of the first codeword and the second codeword, number of code blocks, number of columns associated with systematic part of parity check matrices, maximum padding constraint and step size.

6. The method as in claim 1, wherein the sub-matrix dimension is determined based on the transport block size of the first codeword, the transport block size of the second codeword is determined based on at least one of the sub-matrix dimension, the transport block size of the first codeword, number of columns associated with systematic part of parity check matrices, and modulation and coding rate.

7. The method as in claim 1, further comprising:
encoding the first code blocks and the second code blocks using the sub-matrix dimension; and
outputting first encoded code blocks and second encoded code blocks corresponding to the first codeword and the second codeword respectively.

8. The method as in claim 1, further comprising:
rate matching the first encoded code blocks and the second encoded code blocks; and
outputting first rate-matched code blocks and second rate-matched code blocks corresponding to the first codeword and the second codeword respectively.

9. An apparatus, comprising:
at least one processor; and
at least one memory including compute program instructions,
wherein the at least one memory and computer program instructions are configured to, with the at least one processor, cause the apparatus at least to:
receive a first codeword and a second codeword;
segment the first codeword and the second codeword based on transport block size and code rate to provide a sub-matrix dimension; and
output the sub-matrix dimensioned code blocks of the first codeword and the second codeword as a first code blocks and second code blocks.

10. The apparatus as in claim 9, wherein the transport block size includes cyclic redundancy check overhead.

11. The apparatus as in claim 9, wherein the first codeword and the second codeword is segmented with a single codeword segmentation.

12. The apparatus as in claim 9, wherein the segmenting mechanism is selected based on encoding and decoding capabilities determined using radio resource control signaling.

13. The apparatus as in claim 9, wherein the sub-matrix dimension is determined based on at least one of the transport block sizes of the first codeword and the second codeword, number of code blocks, number of columns associated with systematic part of parity check matrices, maximum padding constraint and step size.

14. The apparatus as in claim 9, wherein the sub-matrix dimension is determined based on the transport block size of the first codeword, the transport block size of the second codeword is determined based on at least one of the sub-matrix dimension, the transport block size of the first codeword, number of columns associated with systematic part of parity check matrices, and modulation and coding rate.

15. The apparatus as in claim 9, wherein the at least one memory and computer program instructions are further configured to, with the at least one processor, cause the apparatus at least to:
encode the first code blocks and the second code blocks using the sub-matrix dimension; and
output first encoded code blocks and second encoded code blocks corresponding to the first codeword and the second codeword respectively.

16. The apparatus as in claim 9, wherein the at least one memory and computer program instructions are further configured to, with the at least one processor, cause the apparatus at least to:
rate matching the first encoded code blocks and the second encoded code blocks; and
outputting first rate-matched code blocks and second rate-matched code blocks corresponding to the first codeword and the second codeword respectively.

17. An apparatus, comprising:
at least one processor; and
at least one memory including compute program instructions,
wherein the at least one memory and computer program instructions are configured to, with the at least one processor, cause the apparatus at least to:
receive first rate-matched code blocks and second rate-matched code blocks corresponding to a first codeword and a second codeword respectively;
rate de-match the first rate-matched code blocks and the second rate-matched code blocks; and
output first rate de-matched code blocks and second rate de-matched code blocks corresponding to the first codeword and the second codeword respectively.

18. The apparatus as in claim 17, wherein the at least one memory and computer program instructions are further configured to, with the at least one processor, cause the apparatus at least to:
receive the first rate-dematched code blocks and the second rate-dematched code blocks;
decode the first rate-dematched code blocks and the second rate-dematched code blocks using a sub-matrix dimension; and
output first decoded code blocks and second decoded code blocks corresponding to the first codeword and the second codeword respectively.

19. The apparatus as in claim 18, wherein hybrid automatic repeat request feedback for both codewords is sent when the first decoded code blocks are found with errors.

20. The apparatus as in claim 18, wherein the sub-matrix dimension is determined based on at least one of the transport block sizes of the first codeword and the second codeword, number of code blocks, number of columns associated with systematic part of parity check matrices, maximum padding constraint and step size.
